(19) United States
(12) Patent Application Publication
(10) Pub. No.: US 2009/0011598 A1
(43) Pub. Date: Jan. 8, 2009

(54) Method of manufacturing semiconductor device including silicon carbide substrate

(75) Inventors: Masanori Nagaya, Kariya-city (JP); Eiichi Okuno, Mizuho-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/155,769

(22) Filed: Jun. 10, 2008

(30) Foreign Application Priority Data
Jul. 5, 2007 (JP) 2007-177283

(51) Int. Cl. H01L 21/04

(52) U.S. Cl. 438/692; 257/E21.054

(57) ABSTRACT

In a manufacturing method of a silicon carbide semiconductor device, a silicon carbide substrate is prepared by slicing an ingot that is made of silicon carbide single crystal. The silicon carbide substrate is heat treated for exposing a substrate defect generated at a surface portion of the silicon carbide substrate and the surface portion of the silicon carbide substrate is chemical-mechanical polished in such a manner that the exposed substrate defect is removed. Then, a semiconductor element is formed on the silicon carbide substrate.

### CROSS REFERENCE TO RELATED APPLICATION

The present application is based on and claims priority to Japanese Patent Application No. 2007-177283 filed on Jul. 5, 2007, the contents of which are incorporated in their entirety herein by reference.

### BACKGROUND OF THE INVENTION

1. Field of the Invention

The present invention relates to a manufacturing method of a semiconductor device that includes a substrate made of silicon carbide (SiC).

2. Description of the Related Art

Conventionally, an SiC substrate is formed by slicing an ingot made of an SiC single crystal. The sliced SiC substrate may have a substrate defect, for example, a crystal strain due to a damage that is generated at a slicing process. Thus, when a semiconductor device is manufactured using the SiC substrate, a surface portion of the sliced SiC substrate is lapped and the SiC substrate is treated with a chemical mechanical polishing process (CMP process) for removing the substrate defect, before forming a semiconductor element on the SiC substrate, for example, as described in JP-A-7-80770.

However, the substrate defect may include a crystal strain. The crystal strain is exposed by an anneal process during forming the semiconductor element, but the crystal strain is difficult to be observed before the CMP process. Thus, it is difficult to know a thickness of the SiC substrate that is required to be polished at the CMP process for removing the substrate defect. Therefore, conventionally, a predetermined thickness of the SiC substrate is removed. However, when the substrate defect is located at a deep portion of the SiC substrate, the substrate defect may remain. In contrast, when the substrate defect is located at a shallow portion of the SiC substrate, the CMP process takes extra time to remove a portion of the SiC substrate that is not required to be removed.

### SUMMARY OF THE INVENTION

In view of the foregoing problems, it is an object of the present invention to provide a method of manufacturing a semiconductor device including a silicon carbide substrate.

According to an aspect of the invention, a method of manufacturing a silicon carbide semiconductor device, includes: slicing an ingot that is made of silicon carbide single crystal for preparing a silicon carbide substrate; heat-treating the silicon carbide substrate for exposing a substrate defect that is generated at a surface portion of the silicon carbide substrate; chemical-mechanical polishing the surface portion of the silicon carbide substrate in such a manner that the exposed substrate defect is removed; and forming a semiconductor element on the silicon carbide substrate.

In the present manufacturing method, the chemical-mechanical polishing process (CMP process) can be performed while observing the substrate defect. Thus, the substrate defect can be removed with a high degree of certainty even when the substrate defect is located at a deep portion of the SiC substrate. In addition, the CMP process can be finished before taking extra time to polish a portion that is not required to be removed.

### BRIEF DESCRIPTION OF THE DRAWINGS

Additional objects and advantages of the present invention will be more readily apparent from the following detailed description of preferred embodiments when taken together with the accompanying drawings. In the drawings:

FIG. 1 is a flow diagram illustrating a manufacturing process of an SiC semiconductor device according to an embodiment of the invention and a manufacturing process of an SiC semiconductor device according to a comparative example;

FIGS. 2A-2C are schematic diagrams illustrating an SiC substrate at each process that is illustrated in FIG. 1; and

FIG. 3 is a graph showing defect densities of the SiC semiconductor devices formed by the manufacturing process according to the embodiment and the manufacturing process according to the comparative example.

### DETAILED DESCRIPTION OF THE PREFERRED EMBODIMENTS

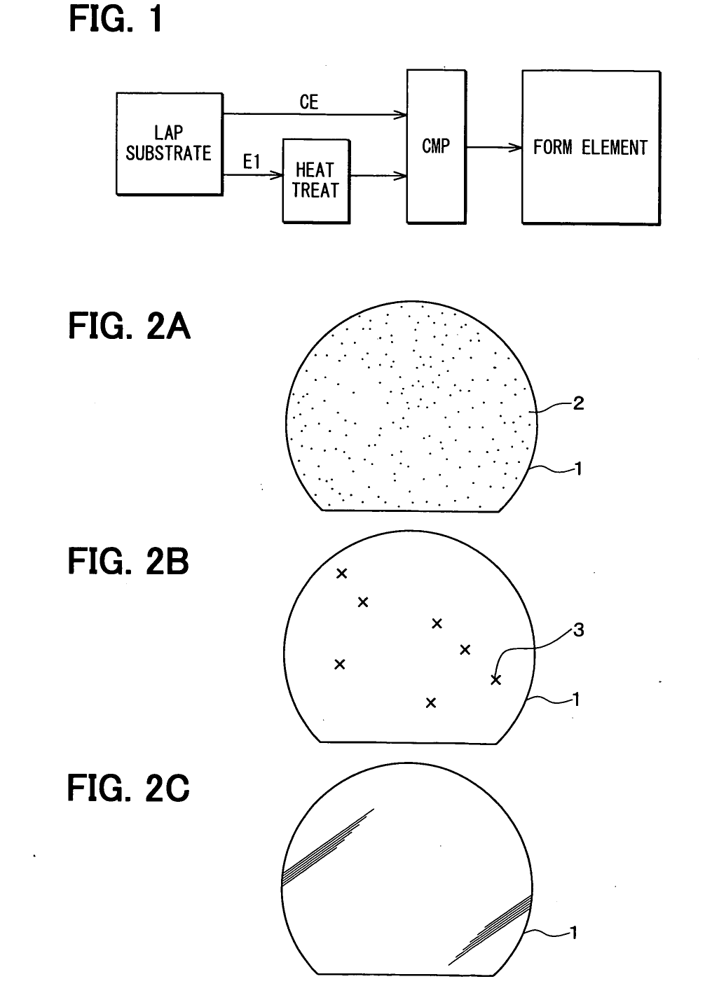

A method of manufacturing an SiC semiconductor device according to an embodiment of the invention will be described with reference to FIGS. 1-2C.

At first, an SiC substrate 1 is prepared by slicing an ingot made of an SiC single crystal. At the present stage, a surface of the SiC substrate 1 is not polished. Thus, the SiC substrate 1 has a surface roughness 2 as illustrated in FIG. 2A.

Then, the surface of the SiC substrate 1 is lapped, and thereby the surface roughness 2 of the SiC substrate 1 is almost removed. At the present time, substrate defects remain at a surface portion of the SiC substrate 1. However, the substrate defects are difficult to be observed. In a manufacturing process according to a comparative example (CE), the SiC substrate 1 is treated with a CMP process just after the lapping process, as a manner similar to the prior art. In a manufacturing process according to the present embodiment (E1), the substrate defects generated at the surface portion of the SiC substrate 1 are exposed before the CMP process.

Specifically, the SiC substrate 1 is disposed in a heating apparatus and is treated at a temperature in a range from about 1000+ C. to about 1100° C., for example. The SiC substrate 1 is heat-treated under an atmosphere in which the surface of the SiC substrate 1 is not oxidized, that is, under a nonoxidizing atmosphere. Thereby, as illustrated in FIG. 2B, the substrate defects 3 are exposed and can be observed. Once the substrate defects 3 are exposed, the substrate defects 3 keep the exposed state even after the temperature of the SiC substrate 1 is decreased. Thus, even when the temperature of the SiC substrate 1 is decreased before the CMP process, the substrate defects 3 can be observed.

Then, the surface portion of the SiC substrate 1 is mirror-polished by the CMP process. Because the substrate defects 3 can be observed during the CMP process, the CMP process is finished when the substrate defects 3 are removed, as illustrated in FIG. 2C, or when a defect density is reduced to a level at which the substrate defect 3 has no effect on a semiconductor element that is formed at a later process. In the manufacturing process according to the present embodiment, the CMP process can be performed while observing the substrate defects 3. Thus, the substrate defects 3 can be removed with a high degree of certainty even when the substrate defects 3 are located at a deep portion of the SiC substrate 1. In addition, the CMP process can be finished before taking extra time to polish a portion that is not required to be removed.

After the SiC substrate 1 is treated with the CMP process, a semiconductor element, for example, a power metal-oxide semiconductor field-effect transistor (power MOSFET) is formed using the SiC substrate 1. When the SiC substrate 1 is formed by the manufacturing process according the present embodiment, the SiC semiconductor device is less affected by the substrate defects 3.

As described above, in the manufacturing process according to the present embodiment, the substrate defects 3 generated at the surface portion of the SiC substrate 1 are exposed by the heat treatment before the CMP process. Thus, the CMP process can be performed while observing the substrate defects 3. Thereby, the substrate defects 3 can be removed with a high degree of certainty even when the substrate defects 3 are located at a deep portion of the SiC substrate 1. In addition, the CMP process can be finished before taking extra time to polish a portion that is not required to be removed.

In order to verify the above-described effect, a density of the observed substrate defects 3 can be detected at time T1 after a drift layer is formed on the SiC substrate 1 and at time T2 after an anneal is performed for activating an impurity that is ion-implanted in the drift layer.

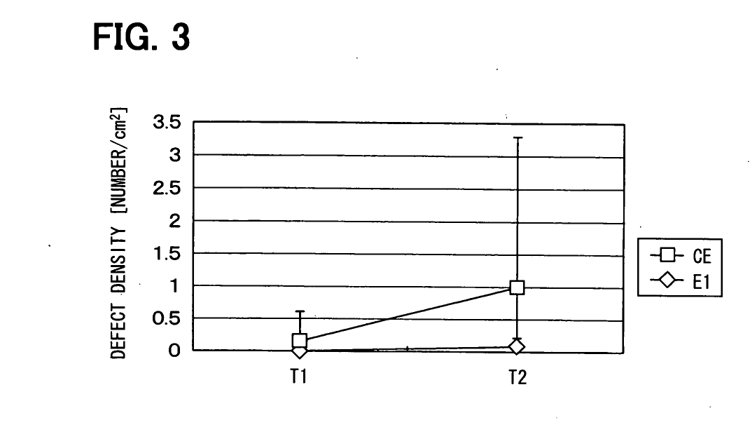

When the SiC substrate 1 is formed by the manufacturing process according to the present embodiment (E1), the substrate defects 3 generated at the surface portion of the SiC substrate 1 are exposed by the heat treatment before the CMP process and the substrate defects 3 are removed by the CMP process with a high degree of certainty. Thus, the number of the observed substrate defects 3 changes little between time T1 and time T2, as shown in FIG. 3. In contrast, when the SiC substrate 1 is formed by the manufacturing process according to the comparative example (CE), the CMP process is performed in a state where the substrate defects 3 cannot be observed. Thus, a part of the substrate defects 3 remain after the CMP process and the remaining substrate defects 3 are exposed by the activation anneal.

As a result, when the substrate defects 3 generated at the surface portion of the SiC substrate 1 are exposed by the heat treatment before the CMP process, the above-described effect can be obtained.

### Other Embodiments

Although the present invention has been fully described in connection with the preferred embodiments thereof with reference to the accompanying drawings, it is to be noted that various changes and modifications will become apparent to those skilled in the art.

In the above-described embodiment, the heat treatment is performed under the atmosphere at which the surface of the SiC substrate 1 is not oxidized, as an example. Alternatively, the heat treatment can be performed under an atmosphere at which the surface of the SiC substrate 1 is oxidized. In the present case, the surface portion of the SiC substrate 1 is removed with the oxide film at the CMP process. Thereby, above-described effect can be obtained.

In the above-described embodiment, the heat treatment is performed at a temperature in a range from about 1000° C. to about 1100° C. Alternatively, the temperature may be greater than 1100° C.

Such changes and modifications are to be understood as being within the scope of the present invention as defined by the appended claims.

What is claimed is:

1. A method of manufacturing a silicon carbide semiconductor device, comprising:
slicing an ingot that is made of silicon carbide single crystal for preparing a silicon carbide substrate;
heat-treating the silicon carbide substrate for exposing a substrate defect that is generated at a surface portion of the silicon carbide substrate;
chemical-mechanical polishing the surface portion of the silicon carbide substrate in such a manner that the exposed substrate defect is removed; and
forming a semiconductor element on the silicon carbide substrate.

2. The method according to claim 1, wherein
the heat treatment is performed at a temperature in a range from about 1000° C. to about 1100° C.

3. The method according to claim 1, wherein
the heat treatment is performed under a nonoxidizing atmosphere.

4. The method according to claim 1, further comprising
lapping the silicon carbide substrate before the heat treatment.
